(19) United States
(12) Patent Application Publication
(10) Pub. No.: US 2025/0139327 A1
(43) Pub. Date: May 1, 2025

(54) MODEL OPERATOR PROCESSING METHOD AND DEVICE, ELECTRONIC EQUIPMENT AND STORAGE MEDIUM

(71) Applicant: BEIJING BAIDU NETCOM SCIENCE TECHNOLOGY CO., LTD., Beijing (CN)

(72) Inventors: Liang Shen, Beijing (CN); Jinle Zeng, Beijing (CN); Hongxiang Hao, Beijing (CN); Weibao Gong, Beijing (CN); Dianhai Yu, Beijing (CN); Haifeng Wang, Beijing (CN)

(73) Assignee: BEIJING BAIDU NETCOM SCIENCE TECHNOLOGY CO., LTD., Beijing (CN)

(21) Appl. No.: 18/895,722

(22) Filed: Sep. 25, 2024

(30) Foreign Application Priority Data
Oct. 17, 2023 (CN) 202311345985.7

(51) Int. Cl. G06F 30/20

(52) U.S. Cl. CPC G06F 30/20

(57) ABSTRACT

A method for processing a model operator includes: determining an operator set for model networking, wherein the operator set comprises a plurality of operators; determining a storage amount occupied by an output tensor of each operator in the operator set and a computation time period consumed in a forward computation of each operator in the operator set; and determining a first operator participating in recomputation in a model from the operator set, based on the storage amounts and the computation time periods of the plurality of operators.

### CROSS-REFERENCE TO RELATED APPLICATION

This application claims priority to and benefits of Chinese Patent Application Serial No. 202311345985.7, filed with the State Intellectual Property Office of P. R. China on Oct. 17, 2023, the entire content of which is incorporated herein by reference.

### TECHNICAL FIELD

The present disclosure relates to the technical field of deep learning, in particular to a method and an apparatus for processing a model operator, an electronic device, and a storage medium.

### BACKGROUND

In the field of deep learning, recomputation is one of the technical paths to implement large model training. In the existing recomputation process, the recomputation is performed uniformly on the operators, which casing a low efficiency in performing the recomputation.

### SUMMARY

According to an aspect of the present disclosure, a method for processing a model operator is provided, including: determining an operator set for model networking, in which the operator set includes a plurality of operators; determining, for each operator in the operator set, a storage amount occupied by an output tensor of the operator and a computation time period consumed in a forward computation of the operator; and determining a first operator participating in recomputation in a model from the operator set, based on the storage amount and the computation time period of the operator.

According to another aspect of the present disclosure, an electronic device is provided, including: at least one processor; and a memory communicatively coupled to the at least one processor; in which the memory stores instructions executable by the at least one processor, the instructions are executed by the at least one processor to cause the at least one processor to perform the method for processing a model operator according to the embodiment of the aspect described above.

According to another aspect of the present disclosure, a non-transitory computer-readable storage medium with computer instructions stored thereon is provided, having stored computer programs/instructions thereon, in which the computer instructions are configured to cause the computer to perform the method for processing a model operator according to the embodiment of the aspect described above.

It is appreciated that what is described in this section is not intended to identify key or important features of embodiments of the present disclosure, nor is it intended to limit the scope of the present disclosure. Other features of the present disclosure will be readily understood by the following specification.

### BRIEF DESCRIPTION OF THE DRAWINGS

The accompanying drawings are used for a better understanding of the disclosure and do not constitute a limitation of the present disclosure.

FIG. 1 is a flowchart illustrating a method for processing a model operator according to an embodiment of the present disclosure;

FIG. 2 is a flowchart illustrating another method for processing a model operator according to an embodiment of the present disclosure;

FIG. 3 is a flowchart illustrating another method for processing a model operator according to an embodiment of the present disclosure;

FIG. 4 is a flowchart illustrating another method for processing a model operator according to an embodiment of the present disclosure;

FIG. 5 is a schematic diagram illustrating a process of merging operators according to an embodiment of the present disclosure;

FIG. 6 is a flowchart illustrating another method for processing a model operator according to an embodiment of the present disclosure;

FIG. 7 is a schematic diagram illustrating a process of performing forward computation on an operator according to an embodiment of the present disclosure;

FIG. 8 is a schematic diagram illustrating a process of performing a recomputation on an operator according to an embodiment of the present disclosure;

FIG. 9 is a schematic diagram illustrating a hybrid parallel model networking according to an embodiment of the present disclosure;

FIG. 10 is a flowchart illustrating another method for processing a model operator according to an embodiment of the present disclosure;

FIG. 11 is a structure diagram illustrating an apparatus for processing a model operator according to an embodiment of the present disclosure;

FIG. 12 is a block diagram illustrating an electronic device configured to implement the method for processing a model operator according to an embodiment of the present disclosure.

### DETAILED DESCRIPTION

Exemplary embodiments of the present disclosure are described hereinafter in conjunction with the accompanying drawings, which include various details of the embodiments of the present disclosure in order to aid in understanding, and should be considered exemplary only. Accordingly, one of ordinary skill in the art should recognize that various changes and modifications can be made to the embodiments described herein without departing from the scope and spirit of the present disclosure. Similarly, descriptions of well-known features and structures are omitted from the following description for the sake of clarity and brevity.

A method and an apparatus for processing a model operator, an electronic device, and a storage medium are described below with reference to the accompanying drawings in the embodiments of the present disclosure.

Artificial Intelligence (AI) is a research discipline that is configured to study enabling computers to simulate certain thought processes and intelligent behaviors (e.g., learning, reasoning, thinking, planning, etc.) in life. The AI has both hardware-level and software-level technologies. The AI hardware technology generally includes several aspects such as computer vision technology, speech recognition technology, natural language processing technology and learning/deep learning of natural language processing technology, big data processing technology, and knowledge graph technology.

Natural language processing (NLP) is an important direction in the field of computer science and artificial intelligence, which studies various theories and methods that may realize effective communication between humans and computers in natural language. The NLP is a science that is integrated with linguistics, computer science, and mathematics. The NLP is mainly applied to aspects such as machine translation, public opinion monitoring, automatic summarization, viewpoint extraction, text categorization, question answering, text semantic comparison, and speech recognition.

Deep learning (DL) is a new research direction in the field of machine learning (ML), which is introduced into the ML to get closer to the AI, the original goal. The DL is the process of learning the intrinsic laws and representational hierarchy of the sample data. The information obtained from the learning process can be of great help in the interpretation of data such as text, images, and sounds. The ultimate goal of DL is to make machines capable of analytical learning and recognize data such as text, images, and sounds, like humans are capable of. The DL is a complex machine learning algorithm that has achieved results in speech and image recognition that far exceed previous related art.

Machine translation is also known as automatic translation, which is the process of transforming one natural language (source language) into another natural language (target language) by using a computer. The machine translation is a branch of computational linguistics and to realize the machine translation is one of the goals of the AI.

FIG. 1 is a flowchart illustrating a method for processing a model operator according to an embodiment of the present disclosure.

As shown in FIG. 1, the method for processing a model operator, may include the following steps S101 to S103.

At S101, an operator set for model networking is determined, in which the operator set includes a plurality of operators.

It should be noted that an execution subject of the method for processing a model operator in the embodiments of the present disclosure may be a hardware device with a data processing capability and/or the necessary software required to drive the work of the hardware device. Optionally, the execution subject may include a server, a user terminal, and other intelligent devices. Optionally, the user terminal includes, but is not limited to, a cell phone, a computer, an intelligent voice interaction device, and the like. Optionally, the server includes, but is not limited to, a network server, an application server, a server of a distributed system, or a server that incorporates a block-chain, etc. The embodiments of the present disclosure are not specifically limited.

In some implementations, the operator set for the model networking may be determined based on information such as application scenarios and structures of the model networking. Different application scenarios and structures correspond to different operator sets. Optionally, the model networking is applicable to scenarios such as image processing, target detection, speech recognition, text generation, etc. Optionally, the structure of the model networking may be a structure of ‘hybrid parallel+Transformer’.

Optionally, the ‘hybrid parallel+Transformer structure’ structure may include, but is not limited to, a combination of data parallel and Transformer, a combination of model parallel and Transformer, a combination of pipeline parallel and Transformer, and a combination of model parallel and pipeline parallel.

In some implementations, the operator set for the model networking may be determined based on the performance of the operators. For example, if a convolution operator is used for image processing, a plurality of convolution operators are included in an operator set for model networking in an image processing scenario.

For example, an operator set for the ‘Transformer’ networking includes operators such as an operator ‘FA’, an operator ‘Matmul’, an operator ‘ReduceScatter’, and an operator ‘Allgather’, etc.

At S102, for each operator in the operator set, a storage amount occupied by an output tensor of the operator and a computation time period consumed in a forward computation of the operator is determined.

It may be understood that in a DL framework, the input and output of an operator are generally represented in the form of a tensor, where the input tensor and the output tensor of the operator describes the shape and content of the data. The tensor is a multidimensional array that may be understood as a high-dimensional matrix, and the tensor may be viewed as an extension of a scalar, a vector, and a matrix.

In some implementations, the storage amount occupied by the output tensor of the operator may be determined based on a parameter input by the operator. Optionally, the storage amount occupied by the output tensor of the operator may be computed based on parameters such as a batch size (batch_size, B), a sequence length (sequence_len, S), a dimension (size) of the hidden state (hidden_size, H), a model parallelism degree (mp_degree(M)), a number of heads (num_head, A), a dimension (size) of a hidden layer of a feedforward neural network (ffn_hidden_size, H′), etc.

In some implementations, the computation time period consumed in the forward computation of the operator may be determined by analyzing a process of the forward computation of the operator. The process of the forward computation of the operator may also be monitored to obtain a time period from the beginning to the end of the forward computation of the operator, and the time period may be taken as the computation time period consumed during the forward computation of the operator.

At S103, based on the storage amount and the computation time period of the operator, a first operator participating in recomputation in a model is determined from the operator set.

It may be understood that a cost performance for the operator to participate in the recomputation may be reflected based on the storage amount and the computation time period corresponding to the operator. The greater of the storage amount corresponding to the operator and the smaller of the computation time period indicates the higher cost performance for the operator to participate in the recomputation; and the smaller of the storage amount corresponding to the operator and the greater of the computation time period indicates the lower cost performance for the operator to participate in the recomputation.

In some implementations, the plurality of operators in the operator set may be screened for recomputation to improve the efficiency of using the graphics memory by the operator and to improve the computational performance. Optionally, a ratio of a storage amount corresponding to an output tensor of each operator to a computation time period of the forward computation of the corresponding operator may be computed. The first operator participating in the recomputation in the model is determined from the operator set based on the ratio.

Optionally, an operator with a high cost performance for participating in the recomputaion may be determined as the first operator from the operator set, based on a ratio of the storage amount and the computation time period.

According to the method for processing a model operators provided in embodiments of the present disclosure, the first operator that is suitable to participate in the recomputation is determined by determining the operator set for the model networking and obtaining the storage amount occupied by the output tensor of each operator the operator set and the computation time period consumed in the forward computation of each operator the operator set. The operators with low cost performance for participating in recomputation are eliminated during the recomputation, to realize high efficiency in graphics memory swapping performance, and make the sacrifice of unit graphics memory to swap for more computational performance. The computational performance of the model may be improved by efficiently using the graphics memory. Fine control of the operators can be performed for each category of operators in the model.

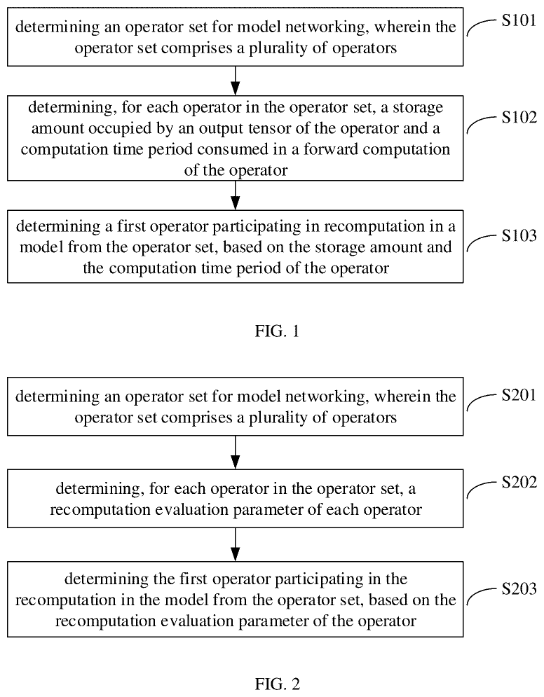

FIG. 2 is a flowchart illustrating a method for processing a model operator according to an embodiment of the present disclosure.

As shown in FIG. 2, the method for processing a model operator, may include the following steps S201 to S203.

At S201, an operator set of model networking is determined, in which the operator set includes a plurality of operators.

The relevant contents of the step S201 can be found in the above embodiment, and will not be repeated herein.

At S202, for each operator in the operator set, a recomputation evaluation parameter of each operator is determined.

It may be understood that the recomputation evaluation parameter of the operator may indicate a size of graphics memory saved by the operator when performing the recomputation in unit time, which is configured to represent the efficiency of the graphics memory swapping performance. The greater the recomputation evaluation parameter of the operator, the greater a possibility that the operator participates in the recomputation.

In some implementations, the plurality of operators in the operator set may be screened for the recomputation based on the recomputation evaluation parameter of the plurality of operators, to improve the efficiency of using the graphics memory by the operator, and to improve the computational performance. Optionally, the recomputation evaluation parameter of the plurality of operators may be determined by analyzing the computational efficiency and the efficiency of using the graphics memory of each operator.

In some implementations, a ratio of a storage amount of an output tensor of an operator to a computation time period of forward computation of the operator may be determined as the recomputation evaluation parameter.

At S203, the first operator participating in the recomputation in the model is determined from the operator set, based on the recomputation evaluation parameter of the operator.

In some implementations, for the operator set, the plurality of operators in the operator set may be sorted according to recomputation evaluation parameters of the plurality of operators, and the first operator participating in the recomputation in the model may be determined based on a sorting result. The first operator may also be determined based on a defined threshold by comparing recomputation evaluation parameters of the plurality of operators in the operator set with a defined threshold respectively.

Optionally, the recomputation evaluation parameters of the plurality of operators may be sorted in a descending order, and the top sorted operators may be determined as the first operator. For example, the plurality of operators in the operator set are sorted in a descending order of the recomputation evaluation parameters, and the top three operators in the sorting result may be determined as the first operator.

Optionally, the recomputation evaluation parameters of the plurality of operators may be sorted in an ascending order, and the bottom sorted operators may be determined as the first operator. For example, the plurality of operators in the operator set are sorted in an ascending order of the recomputation evaluation parameters, and the bottom three in the sorting result operators may be determined as the first operator.

Optionally, the first operator participating in the recomputation in the model is determined from the operator set by comparing the recomputation evaluation parameters of the plurality of operators in the operator set with a defined threshold respectively. The first operator is an operator with a recomputation evaluation parameter greater than or equal to the defined threshold

According to the method for processing a model operators provided in embodiments of the present disclosure, by determining the operator set for the model networking, and determining the recomputation evaluation parameter of each operator in the operator set, the first operator that is suitable to participate in the recomputation is determined based on the recomputation evaluation parameter of the operator. The operators with low cost performance for participating in recomputation are eliminated during the recomputation, to realize high efficiency in graphics memory swapping performance, and make the sacrifice of unit graphics memory to swap for more computational performance. The computational performance of the model may be improved by efficiently using the graphics memory. Fine control of the operators can be performed for each category of operators in the model.

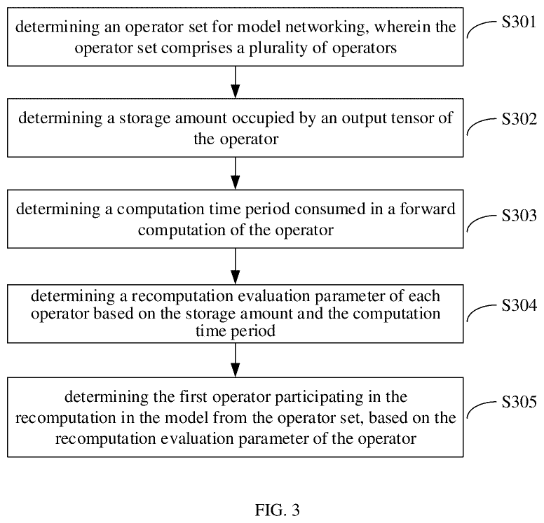

FIG. 3 is a flowchart illustrating a method for processing a model operator according to an embodiment of the present disclosure.

As shown in FIG. 3, the method for processing a model operator, may include the following steps S101 to S103.

At S301, an operator set for model networking is determined, in which the operator set includes a plurality of operators.

The relevant contents of the step S301 can be found in the above embodiment, and will not be repeated herein.

At S302, a storage amount occupied by an output tensor of each operator is determined.

It may be understood that in a DL framework, the input and output of the operator are generally represented in the form of a tensor, where the input tensor and the output tensor of the operator describes the shape and content of the data. The tensor is a multidimensional array that may be understood as a high-dimensional matrix, and the tensor may be viewed as an extension of a scalar, a vector, and a matrix.

In some implementations, the storage amount occupied by the output tensor of the operator may be determined based on a parameter input by the operator. Optionally, the storage amount occupied by the output tensor of the operator may be computed based on parameters such as a batch size (batch_size, B), a sequence length (sequence_len, S), a dimension (size) of the hidden state (hidden_size, H), a model parallelism degree (mp_degree(M)), a number of heads (num_head, A), a dimension (size) of the hidden layer of a feedforward neural network (ffn_hidden_size, H′), etc.

At S303, a computation time period consumed in a forward computation of the operator is determined.

In some implementations, the computation time period consumed in the forward computation of the operator may be determined by analyzing a process of the forward computation of the operator. The process of the forward computation of the operator may also be monitored to obtain a time period from the beginning to the end of the forward computation of the operator, and the time period may be taken as the computation time period consumed during the forward computation of the operator.

At S304, a recomputation evaluation parameter of each operator is determined based on the storage amount and the computation time period.

In some implementations, a ratio of the storage amount occupied by the output tensor of the operator to the computation time period consumed in the forward computation of the operator is obtained, and the ratio is determined as the recomputation evaluation parameter. Optionally, an equation for computing the recomputation evaluation parameter is provided as follows:

$$η = \frac{Mem}{Time} \qquad ( 1 )$$

In the equation, ‘η’ represents the recomputation evaluation parameter of the operator, ‘Mem’ represents the storage amount occupied by the output tensor, and ‘Time’ represents the computation time period consumed in the forward computation of the operator.

In some implementations, the recomputation evaluation parameter of the operator may indicate the size of the graphics memory saved by the operator when performing the recomputation in unit time. The greater the recomputation evaluation parameter of the operator, the greater a possibility that the operator participates in recomputation.

For example, for operators such as ‘Layernorm’, having the feature of fast computation and large graphics memory. The fast computation refers to short computation time, and the large graphics memory size refers to the large storage amount, then the recomputation evaluation parameter corresponding to the operator ‘Layernorm’ is large, thus the operator ‘Layernorm’ needs to participate in the recomputation. For operators such as ‘MatMul’, the computation is heavy, the computation time period is long, and the efficiency for recomputation is low, thus the operator ‘MatMul’ is less possibly to participate in the recomputation.

In some implementations, the storage amount occupied by the output tensor and the computation time period consumed in the forward computation of the operator may be analyzed and computed offline. The recomputation evaluation parameter of the operator may be obtained by analyzing and computing the storage amount and the computation time period offline.

At S305, the first operator participating in the recomputation in the model is determined from the operator set, based on the recomputation evaluation parameter of the operator.

In some implementations, the plurality of operators in the operator set may be sorted according to recomputation evaluation parameters of the plurality of operators, and the first operator may be selected from the operator set based on a sorting result. In the recomputation, the operators with high cost performance for participating in recomputation may be utilized to implement high efficiency in graphics memory swapping performance.

Optionally, the plurality of operators in the operator set are sorted in a descending order of the recomputation evaluation parameters of the plurality of operators, and top N operators are selected as the first operator. Or, the plurality of operators in the operator set are sorted in an ascending order of the recomputation evaluation parameters of the plurality of operators, and bottom N operators are selected as the first operator; and in which N is a natural number greater than or equal to 1.

For example, if N is equal to 5, the top 5 operators that are sorted in a descending order may be selected as the first operator. Or, the bottom 5 operators that are sorted in an ascending order may also be selected as the first operator.

In some implementations, a defined threshold value of the recomputation evaluation parameter may be defined. The first operator may be selected from the operator set based on the defined threshold value. In the recomputation, the operators with high cost performance for participating in recomputation may be utilized to implement high efficiency graphics memory swapping performance.

Optionally, the recomputation evaluation parameters of the plurality of operators in the operator set are compared with the defined threshold respectively; and an operator with a recomputation evaluation parameter greater than or equal to the defined threshold is selected as the first operator.

According to the method for processing a model operators provided in embodiments of the present disclosure, the recomputation evaluation parameter is determined by determining the operator set for the model networking and determining the storage amount occupied by the output tensor of each operator and the computation time period consumed in the forward computation of each operator. The first operator that is suitable to participate in the recomputation is determined based on the recomputation evaluation parameter of the operator. The operators with low cost performance for participating in recomputation are eliminated during the recomputation, to realize high efficiency in graphics memory swapping performance, and make the sacrifice of unit graphics memory to swap for more computational performance. The computational performance of the model may be improved by efficiently using the graphics memory. Fine control of the operators can be performed for each category of operators in the model.

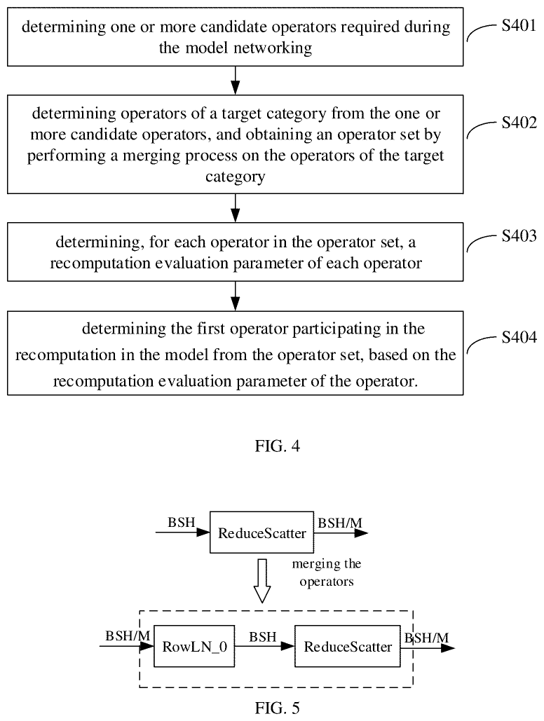

FIG. 4 is a flowchart illustrating a method for processing a model operator according to an embodiment of the present disclosure.

As shown in FIG. 4, the method for processing a model operator, may include the following steps S401 to S404.

At S401, one or more candidate operators required during model networking are determined.

At S402, operators of a target category are determined from the one or more candidate operators, and an operator set is obtained by performing a merging process on the operators of the target category.

In some implementations, the one or more candidate operators required during the model networking may be determined based on information such as application scenarios and structures of the model networking, in combination with the performance of the operator.

It may be understood that if an operator of a category does not require a forward input and a forward output during a backward computation, the operator of this category requires special processing. The operator of this category can be merged into an operator previous to the operator, and the merged operator may be considered as one single operator, thus the performance of the model computation may be improved.

In some implementations, a candidate operator that does not require a forward input and a forward output during a backward computation may be determined as an operator of the target category. The operators of the target category are determined from the one or more candidate operators, and the operator set is obtained by performing a merging process on the operators of the target category.

Optionally, for any candidate operator that belongs to the target category, a candidate operator previous adjacent to the any candidate operator may be determined, and a merged operator is obtained by merging the any candidate operator and the previous candidate operator. Further, the operator set is obtained based on the merged operator and remaining candidate operators. For example, the candidate operators include an operator A, an operator B, an operator C, an operator D, and an operator E, in which the operator C is merged into the operator B to obtain a merged operator B′, and then the operator A, the operator D, and the operator E are the remaining candidate operators. An operator set is formed by the remaining candidate operators and the merged operator B′.

For example, if the structure of the model networking is a structure of ‘hybrid parallel+Transformer’, including an operator ‘ReduceScatter’ of the communication category, which does not require the forward input and the forward output during the backward computation. A candidate operator previous to the operator ‘ReduceScatter’ is ‘RowLN’ matrix multiplication. Thus, the merged operator ‘RowLN+ReduceScatter’ is obtained by merging the operator ‘RowLN’ and the operator ‘ReduceScatter’, that is, the operator ‘RowLN_0’ and the operator ‘ReduceScatter’ are taken as a whole as one merged operator.

As shown in FIG. 5, it is a schematic diagram illustrating a process of merging the operators. A merged operator is obtained by merging the operator ‘RowLN_0’ and the operator ‘ReduceScatter’, and the operators in the dashed box in FIG. 5 is the merged operator. BSH indicates a parameter of the operator ‘ReduceScatter’, and BSH/M indicates the output size of the operator ‘ReduceScatter’. The ‘B’ in BSH/M indicates ‘batch_size’, the ‘S’ in BSH/M indicates ‘sequence_len’, the ‘H’ in BSH/M indicates ‘hidden_size’, and the ‘M’ in BSH/M indicates ‘mp_degree’.

At S403, for each operator in the operator set, a recomputation evaluation parameter of each operator is determined.

In some implementations, since the merged operator is formed by a plurality of operators, the recomputation evaluation parameter of the merged operator may be determined based on the storage amount occupied by the output tensor of each candidate operator included in the merged operator and the computation time period consumed in the forward computation of each candidate operator included in the merged operator.

Optionally, the recomputation evaluation parameter of the merged operator is computed based on the above equation (1) by obtaining the storage amount occupied by the output tensor of each candidate operator and the computation time period consumed in the forward computation of each candidate operator.

At S404, the first operator participating in the recomputation in the model is determined from the operator set, based on the recomputation evaluation parameter of the operator.

The relevant contents of the step S404 can be found in the above embodiment, and will not be repeated herein.

According to the method for processing a model operators provided in embodiments of the present disclosure, the operator set is obtained by obtaining one or more candidate operators required during the model networking, determining operators of a target category from the one or more candidate operators, and performing a merging process on the operators of the target category. The recomputation evaluation parameter of each operator in the operator set is determined, and the first operator that is suitable to participate in the recomputation is determined based on the recomputation evaluation parameter of each operator by computing. The operators with low cost performance for participating in recomputation are eliminated during the recomputation, to realize high efficiency in graphics memory swapping performance, and make the sacrifice of unit graphics memory to swap for more computational performance. The computational performance of the model may be improved by efficiently using the graphics memory. Fine control of the operators can be performed for each category of operators in the model.

FIG. 6 is a flowchart illustrating a method for processing a model operator according to an embodiment of the present disclosure.

As shown in FIG. 6, the method for processing a model operator, may include the following steps S601 to S605.

At S601, an operator set for model networking is determined, in which the operator set includes a plurality of operators.

At S602, for each operator in the operator set, a recomputation evaluation parameter of each operator is determined.

At S603, the first operator participating in the recomputation in the model is determined from the operator set, based on the recomputation evaluation parameters of operators.

The relevant contents of the step S601 to step S603 can be found in the above embodiment, and will not be repeated herein.

At S604, a forward computation of the model is performed based on a forward logical order of the plurality of operators in the operator set, and an intermediate result of the first operator is released.

In some implementations, a recomputation may be performed on the operators of the operator set after the first operator is determined. The recomputation includes a forward computation, a forward recomputation, and a backward computation. The recomputation evaluation parameter of the first operator is higher in the forward computation, which indicates that the computation time period corresponding to the first operator is less, thus the forward recomputation time for the first operator is less. Thus, the intermediate result of the first operator may be released to reduce the occupation of the graphics memory.

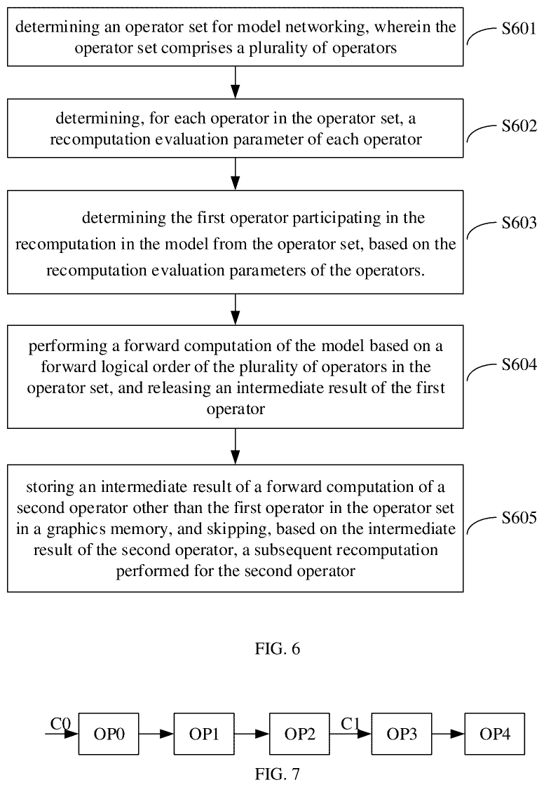

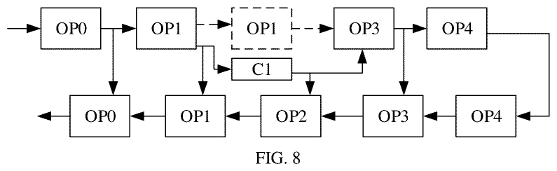

As shown in FIG. 7, it is a schematic diagram illustrating a process of performing forward computation on an operator. There are five operators included in the operator set of one layer of the model: OP0, OP1, OP2, OP3, and OP4, and the OP0, OP1, OP3, and OP4 may be determined as the first operator, and the OP2 may be determined as the second operator based on the recomputation evaluation parameters of each operators. The forward computation of the operators of the layer of the model is performed in a logical order, i.e., the intermediate results of the operators are computed in the order of the OP0, the OP1, the OP2, the OP3, and the OP4, and the intermediate results of the OP0, the OP1, the OP3, and the OP4 are released.

At S605, an intermediate result of a forward computation of a second operator other than the first operator in the operator set is stored in a graphics memory, and a subsequent recomputation performed for the second operator is skipped based on the intermediate result of the second operator.

In some implementations, the first operator is an operator in the operator set that is required to participate in the recomputation, and the second operator is an operator in the operator set that is not required to participate in the recomputation. In one first forward computation, it is determined, based on the recomputation evaluation parameters of the operators, that the second operator does not need to participate in the recomputation in a subsequent process, the intermediate result of the forward computation of the second operator in the operator set may be stored in the graphics memory, thus a subsequent recomputation performed for the second operator can be skipped based on the intermediate result of the second operator. For example, as shown in FIG. 7, the intermediate result of the OP2, i.e., the second operator, obtained by performing the forward computation is C1, and the C1 is stored in the graphics memory.

In some implementations, a forward computation is performed again based on a first logical order of the forward computations of the plurality of operators in the operator set after the intermediate result of the second operator is stored in the graphics memory. The first logical order is the forward logical order.

Optionally, an intermediate result of the forward computation of the first operator is obtained by performing a forward recomputation on the first operator based on a forward input of the first operator. The intermediate result of the second operator is read from the graphics memory in a case where the forward computation reaches the second operator. The forward computation of the second operator is reduced in the forward recomputation, and the overall time consumed for recomputation may be reduced by increasing the usage of the graphics memory to improve the the computational performance.

Further, a backward computation of the model is performed based on the intermediate result of the first operator and the intermediate result of the second operator. Optionally, the backward computation may be performed according to a second logical order of backward computations of the plurality of operators in the operator set.

Optionally, for the first operator, the backward computation is performed on the first operator based on the intermediate result of the first operator and a backward output of a previous operator of the first operator in the backward computation, to obtain a backward output of the first operator, and the backward output of the first operator is input into a next operator of the first operator. The intermediate result of the second operator is read from the graphics memory in a case where the backward computation reaches the second operator. A backward output of the second operator is determined based on the intermediate result of the second operator and a backward output of a previous operator of the second operator in the backward computation, and the backward output of the second operator is input into a next operator of the second operator.

That is, the backward computation is performed on the first operator by inputting the intermediate result of the first operator and the backward output of the previous operator of the first operator in the backward computation into the first operator. As shown in FIG. 8, it is a schematic diagram illustrating a process of performing a recomputation on an operator. For example, for OP1, when performing a backward computation, the input of the OP1 includes the intermediate result of the forward computation of the OP1 and the backward output of the OP2. During a forward recomputation, the recomputation of OP2 may be skipped by reading the C1 stored in the graphics memory, as shown in the dashed part of the FIG. 8.

In some implementations, in the graphics memory, a forward input of an operator on which the forward computation is first performed is stored in a case where the forward computation of the model is performed for a first time. The forward input of the operator on which the forward computation is first performed is read from the graphics memory in a case where another forward computation is performed on the model, and a recomputation is performed by inputting the forward input into the operator on which the forward computation is first performed. As shown in FIG. 7, OP0 is the operator on which the forward computation is first performed when the forward computation of the model is performed for a first time. C0 is the forward input of OP0. The forward computation of OP0 may be performed based on the C0, to obtain the intermediate result of the OP0.

According to the method for processing a model operators provided in embodiments of the present disclosure, by determining the operator set for the model networking, and determining the recomputation evaluation parameter of each operator in the operator set, the first operator that is suitable to participate in the recomputation is determined based on the recomputation evaluation parameters of the operators. The operators with low cost performance for participating in recomputation are eliminated during the recomputation, to realize high efficiency in graphics memory swapping performance, and make the sacrifice of unit graphics memory to swap for more computational performance. The computational performance of the model may be improved by efficiently using the graphics memory. Fine control of the operators can be performed for each category of operators in the model. During the recomputation, the forward computation of the second operator can be reduced by storing the intermediate result of the second operator in the graphics memory, and the computational performance is improved by increasing the usage of graphics memory.

For example, the recomputation of the ‘Transformer’ networking is described. For the ‘Transformer’, the main relevant operators (OP) includes operators such as the operator ‘FA’, the operator ‘Matmul’, the operator ‘ReduceScatter’, and the operator ‘Allgather’, etc. The recomputation evaluation parameters of the operators is determined according to the above equation (1) after merging the operators. A sorting table of the recomputation evaluation parameters of the operators is obtained as shown in table 1.

TABLE 1

| | | computation | storage | recomputation | time | computation |
|---|---|---|---|---|---|---|
| | | time | amount | evaluation | period | equation |
| number | OP name | (time/ms) | (Mem/MB) | parameter η | ratio | (bytes) |
| 1 | RowLN_1 + | 5.37 | 28.0 | 5.21 | 19.3% | BSH/M*2 |
| | ReduceScatter | | | | | |
| 2 | FA | 3.84 | 28.43 | 7.40 | 13.8% | (4BAS + |
| | | | | | | 2BSH)/M |
| 3 | RowLN_0 + | 2.92 | 28.00 | 9.59 | 10.5% | BSH/M*2 |
| | ReduceScatter | | | | | |
| 4 | ColumnLN_0 | 4.65 | 84.00 | 18.08 | 16.7% | 3BSH/M*2 |
| 5 | ColumnLN_1 | 7.96 | 152.00 | 19.11 | 28.6% | 2BSH′/M*2 |
| 6 | ‘Layernorm’ + | 1.38 | 224.00 | 162.91 | 5% | BSH *2 |
| | Allgather | | | | | |
| 7 | ‘Layernorm’ | 0.17 | 28.00 | 169.70 | 0.6% | BSH *2 |
| 8 | Allgather | 1.21 | 224.00 | 185.12 | 4.3% | BSH/M*2 |
| 9 | Silu + Ele | 0.34 | 76.00 | 223.53 | 1.2% | BSH′/M*2 |

As shown in table 1, there are 9 operators included in the operator set, in which the operator number 1, the operator number 3, and the operator number 6 are the merged operators. The plurality of operators in the operator set are sorted in an ascending order of the computed recomputation evaluation parameters of the plurality of operators, and the bottom four operators are selected as the first operator. The top five operators is selected as the second operator. The time period ratio indicates a ratio of a computation time period consumed by each operator to a computation time period consumed by the whole operator set. For example, the ratio of the computation time period consumed time period consumed by the operator ‘FA’ to the computation time period consumed by the whole operator set is 13.8%. The computation equation indicates the size of the output the operator, and the value in the computation equation indicates the size of a storage amount. In the equation, the B indicates ‘batch_size’, the S indicates ‘sequence_len’, the H indicates ‘hidden_size’, the M indicates ‘mp_degree’, the Aindicates ‘num_head’, and the H′ indicates ‘ffn_hidden_size’.

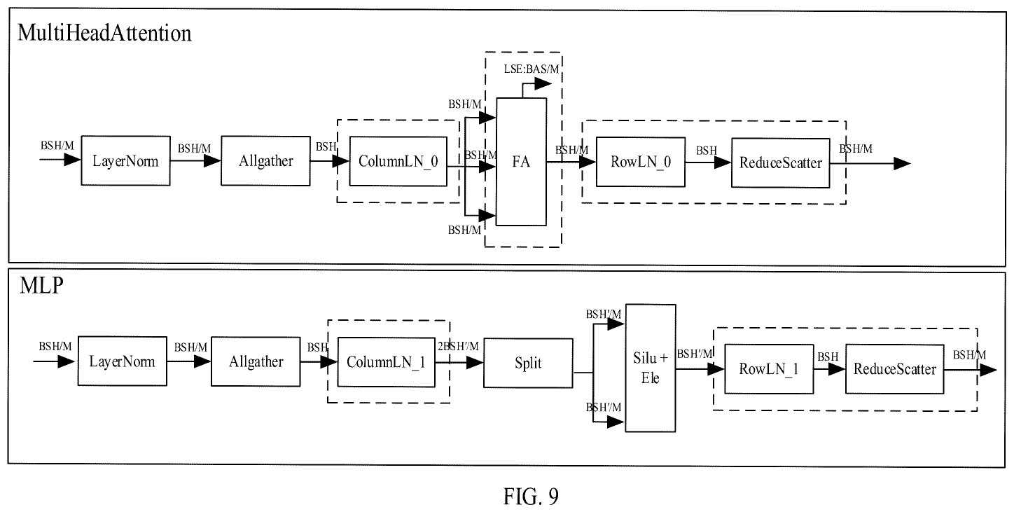

As shown in FIG. 9, it is a schematic diagram illustrating a hybrid parallel model networking. The hybrid parallel model includes a multi head attention network and a multilayer perception (MLP) network.

The multi head attention network includes: an operator ‘LayerNom’, an operator ‘ALLgather’, an operator ‘ColumnLN_0’, an operator ‘FA’, an operator ‘RowLN_0’, and an operator ‘ReduceScatter’. The MLP network includes: an operator ‘LayerNom’, an operator ‘ALLgather’, an operator ‘ColumnLN_1’, an operator ‘Silu+Ele’, an operator ‘RowLN_1’, and an operator ‘ReduceScatter’.

As shown in FIG. 9, the inputs of each operator such as BSH/M, BSH, BSH′/M, etc., indicate the parameters input to the operator. The B indicates the batch size ‘batch_size’, the S indicates the sequence length ‘sequence_len’, the H indicates the dimension of the hidden state ‘hidden_size’, the M indicates the model parallelism degree ‘mp_degree’, the A indicates the number of heads ‘num_head’, and the H′ indicates the dimension of the hidden layer of the feedforward neural network ‘ffn_hidden_size’. There are two outputs of the operator ‘FA’, and the name of the output of the operator ‘FA’ is indicated by LSE, the size of the output of the operator ‘FA’ is indicated by BAS/M.

As shown in FIG. 9, the operators in the dashed box are the second operators. The forward logical order of the operators is also illustrated in FIG. 9.

During the recomputation, the forward computation of the model is performed based on the forward logical order of the operators as illustrated in FIG. 9 in the. The intermediate results of the first operators, i.e., the intermediate results of the bottom four operators in table 1, is released. An intermediate result of the forward computation of the second operator is stored in the graphics memory. An intermediate result of the forward computation of the first operator is obtained by performing a forward recomputation on the first operator based on a forward input of the first operator according to the forward logical order of the operators as illustrated in FIG. 9. The intermediate result of the second operator is read from the graphics memory when the forward computation reaches the second operator. A backward computation of the model is performed based on the intermediate result of the first operator and the intermediate result of the second operator.

For example, in a backward computation of the first operator ‘Allgather’, the backward output of the operator ‘Allgather’ is obtained by performing a backward computation on the operator ‘Allgather’ based on the intermediate result of the operator ‘Allgather’ and a backward output of the operator ‘ColumnLN_0’, and the backward output of the operator ‘Allgather’ is input into the operator ‘LayerNorm’.

For example, in a backward computation of the second operator ‘ColumnLN_1’, the intermediate result of the operator ‘ColumnLN_1’ is read from the graphics memory, and a backward output of the operator ‘ColumnLN_1’ is determined based on the intermediate result of the operator ‘ColumnLN_1’ and the backward output of the operator ‘Silu+Ele’. The backward output of the operator ‘ColumnLN_1’ is input into the operator ‘Allgather’.

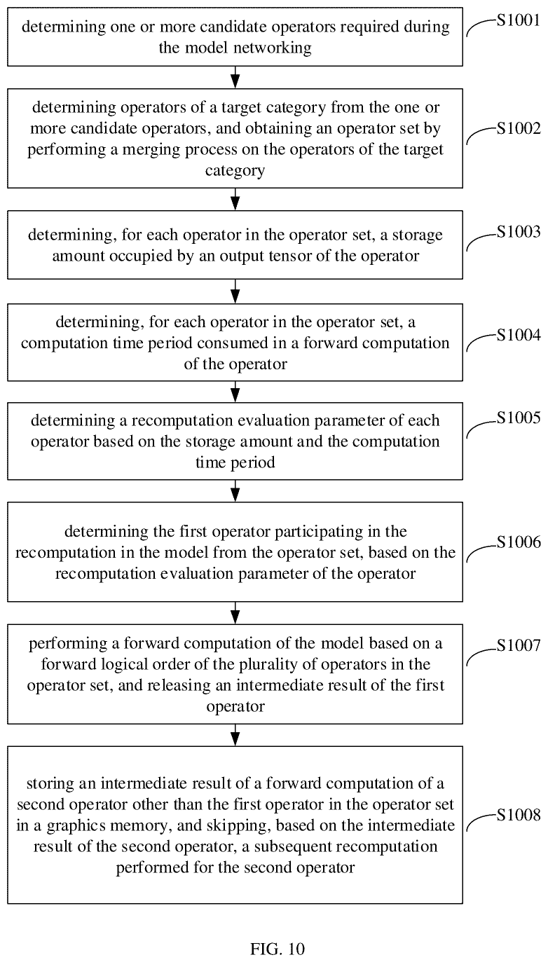

FIG. 10 is a flowchart illustrating a method for processing a model operator according to an embodiment of the present disclosure.

As shown in FIG. 10, the method for processing a model operator, may include the following steps S1001 to S1008.

At S1001, one or more candidate operators required during model networking is determined.

At S1002, operators of a target category is determined from the one or more candidate operators, and an operator set is obtained by performing a merging process on the operators of the target category.

At S1003, for each operator in the operator set, a storage amount occupied by an output tensor of the operator is determined.

At S1004, for each operator in the operator set, a computation time period consumed in a forward computation of the operator is determined.

At S1005, a recomputation evaluation parameter of each operator is determined based on the storage amount and the computation time period.

At S1006, a first operator participating in recomputation in a model is determined from the operator set, based on the recomputation evaluation parameters of the plurality of operators.

At S1007, a forward computation of the model is performed based on a forward logical order of the plurality of operators in the operator set, and an intermediate result of the first operator is released.

At S1008, an intermediate result of a forward computation of a second operator other than the first operator in the operator set is stored in a graphics memory, and a subsequent recomputation performed for the second operator is skipped based on the intermediate result of the second operator.

According to the method for processing a model operators provided in embodiments of the present disclosure, by determining the operator set for the model networking and computing the recomputation evaluation parameter of each operator in the operator set, the first operator that is required to participate in the recomputation is determined based on the recomputation evaluation parameter of the operator. The operators with low cost performance for participating in recomputation are eliminated during the recomputation, to realize high efficiency in graphics memory swapping performance, and make the sacrifice of unit graphics memory to swap for more computational performance. The computational performance of the model may be improved by efficiently using the graphics memory. Fine control of the operators can be performed for each category of operators in the model. In the recomputation, the forward computation of the second operator can be reduced by storing the intermediate result of the second operator in the graphics memory, and the computational performance is improved by increasing the usage graphics memory.

An apparatus for processing a model operator is also provided in an embodiment of the present disclosure, corresponding to the method for processing a model operator provided in the embodiments described above. And since the apparatus is corresponding to the method, the implementation of the method for processing a model operator described above is also applicable to the apparatus for processing a model operator provided in an embodiment of the present disclosure, and will not be described in detail in the following embodiments.

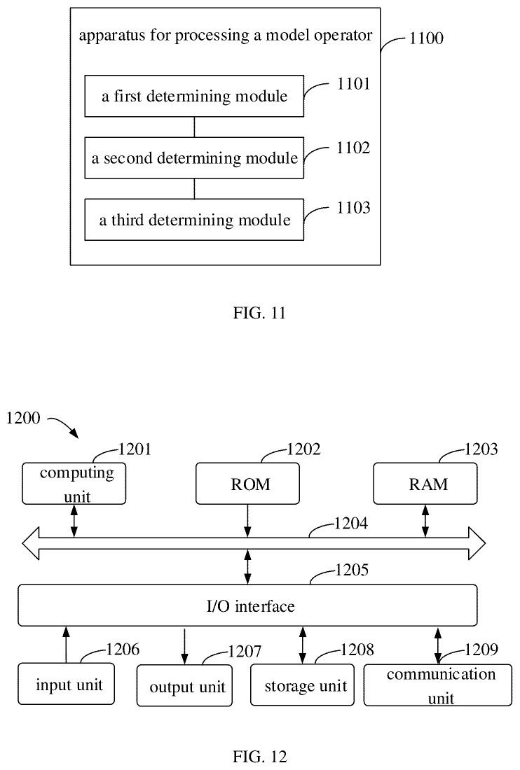

FIG. 11 is a structure diagram illustrating an apparatus for processing a model operator according to an embodiment of the present disclosure.

As shown in FIG. 11, the apparatus 1100 for processing a model operator provided in an embodiment of the present disclosure includes a first determining module 1101, a second determining module 1102, and a third determining module 1103.

The first determining module 1101 is configured to determine an operator set for model networking, in which the operator set includes a plurality of operators.

The second determining module 1102 is configured to determine, for each operator in the operator set, a storage amount occupied by an output tensor of the operator and a computation time period consumed in a forward computation of the operator.

The third determining module 1103 is configured to determine a first operator participating in recomputation in a model from the operator set, based on the storage amount and the computation time period of the operator.

In an embodiment of the present disclosure, the third determining module 1103 is further configured to determine a recomputation evaluation parameter of the operator based on the storage amount and the computation time period; and determine the first operator participating in the recomputation in the model from the operator set, based on the recomputation evaluation parameter of the operator.

In an embodiment of the present disclosure, the third determining module 1103 is further configured to obtain a ratio of the storage amount to the computation time period, and determine the ratio as the recomputation evaluation parameter.

In an embodiment of the present disclosure, the greater the recomputation evaluation parameter of the operator, the greater a possibility that the operator participates in recomputation.

In an embodiment of the present disclosure, the third determining module 1103 is further configured to sort the plurality of operators in the operator set according to recomputation evaluation parameters of the plurality of operators, and select the first operator from the operator set based on a sorting result.

In an embodiment of the present disclosure, the third determining module 1103 is further configured to compare recomputation evaluation parameters of the plurality of operators in the operator set with a defined threshold respectively; and select an operator with a recalculation evaluation parameter greater than or equal to the defined threshold as the first operator.

In an embodiment of the present disclosure, the first determining module 1101 is further configured to determine one or more candidate operators required during the model networking; and determine operators of a target category from the one or more candidate operators, and obtain the operator set by performing a merging process on the operators of the target category.

In an embodiment of the present disclosure, the first determining module 1101 is further configured to determine, for any candidate operator that belongs to the target category, a previous candidate operator adjacent to the any candidate operator, and obtain a merged operator by merging the any candidate operator and the previous candidate operator; and obtain the operator set based on the merged operator and remaining candidate operators.

In an embodiment of the present disclosure, the first determining module 1101 is further configured to determine a candidate operator that does not require a forward input and a forward output during a backward computation as an operator of the target category.

In an embodiment of the present disclosure, the third determining module 1103 is further configured to determine a recomputation evaluation parameter of the merged operator based on a storage amount and a computation time period of an output tensor of each candidate operator included in the merged operator.

In an embodiment of the present disclosure, the third determining module 1103 is further configured to perform a forward computation of the model based on a forward logical order of the plurality of operators in the operator set, and release an intermediate result of the first operator; and store an intermediate result of a forward computation of a second operator other than the first operator in the operator set in a graphics memory, and skip, based on the intermediate result of the second operator, a subsequent recomputation performed for the second operator.

In an embodiment of the present disclosure, the third determining module 1103 is further configured to perform a forward computation based on a first logical order of the forward computations of the plurality of operators in the operator set; obtain an intermediate result of the forward computation of the first operator by performing a forward recomputation on the first operator based on a forward input of the first operator; read the intermediate result of the second operator from the graphics memory in a case where the forward computation reaches the second operator; and perform a backward computation of the model based on the intermediate result of the first operator and the intermediate result of the second operator.

In an embodiment of the present disclosure, the third determining module 1103 is further configured to perform the backward computation according to a second logical order of backward computations of the plurality of operators in the operator set; perform, for the first operator, the backward computation on the first operator based on the intermediate result of the first operator and a backward output of a previous operator of the first operator in the backward computation, obtain a backward output of the first operator, and input the backward output of the first operator into a next operator of the first operator; and read the intermediate result of the second operator from the graphics memory in a case where the backward computation reaches the second operator, determine a backward output of the second operator based on the intermediate result of the second operator and a backward output of a previous operator of the second operator in the backward computation, and input the backward output of the second operator into a next operator of the second operator.

In an embodiment of the present disclosure, the apparatus is further configured to store, in the graphics memory, a forward input of an operator on which the forward computation is first performed in a case where the forward computation of the model is performed for a first time; and read the forward input of the operator on which the forward computation is first performed from the graphics memory in a case where another forward computation is performed on the model, and perform a recomputation by inputting the forward input into the operator on which the forward computation is first performed.

In an embodiment of the present disclosure, the third determining module 1103 is further configured to sort the plurality of operators in the operator set in a descending order of the recomputation evaluation parameters of the plurality of operators, and select top N operators as the first operator; or, sort the plurality of operators in the operator set in an ascending order of the recomputation evaluation parameters of the plurality of operators, and select bottom N operators as the first operator; and in which N is a natural number greater than or equal to 1.

According to the method for processing a model operators provided in embodiments of the present disclosure, the first operator that is suitable to participate in the recomputation is determined based on the recomputation evaluation parameter of the operator by determining the operator set for the model networking and computing the recomputation evaluation parameter of each operator in the operator set. The operators with low cost performance for participating in recomputation are eliminated during the recomputation, to realize high efficiency in graphics memory swapping performance, and make the sacrifice of unit graphics memory to swap for more computational performance. The computational performance of the model may be improved by efficiently using the graphics memory. Fine control of the operators can be performed for each category of operators in the model. During the recomputation, the forward computation of the second operator can be reduced by storing the intermediate result of the second operator in the graphics memory, and the computational performance is improved by increasing the usage graphics memory.

In the technical solution of the present disclosure, the acquisition, storage and application of the personal information of the users are in compliance with relevant laws and regulations, and do not violate public order and morals.

According to embodiments of the present disclosure, it also provides an electronic device, a readable storage medium, and a computer program product.

Referring to FIG. 12, it is a block diagram illustrating an electronic device 1200 according to an embodiment of the present disclosure. The electronic device is intended to represent various types of digital computers, such as laptop computers, desktop computers, workstations, personal digital assistants, servers, blade servers, mainframe computers, and other suitable computers. The electronic device may also represent various types of mobile devices, such as personal digital assistants, cellular phones, smart phones, wearable devices, and other similar computing devices. The components shown herein, their connections and relations, and their functions are merely examples, which are not intended to limit the implementations of the disclosure described and/or required herein.

As shown in FIG. 12, the device 1200 includes a computing unit 1201, configured to execute various appropriate actions and processes according to a computer program/instruction stored in a read-only memory (ROM) 1202 or a computer program/instruction loaded from a storage unit 1208 to a random access memory (RAM) 1203. In the RAM 1203, various programs and data required for the device 1200 may be stored. The computing unit 1201, the ROM 1202 and the RAM 1203 may be connected with each other by a bus 1204. An input/output (I/O) interface 1205 is also connected to the bus 1204.

The plurality of components in the device 1200 are connected to the I/O interface 1205, which include: an input unit 1206, for example, a keyboard, a mouse; an output unit 1207, for example, various types of displays, speakers; a storage unit 1208, for example, a magnetic disk, an optical disk; and a communication unit 1209, for example, a network card, a modem, a wireless transceiver. The communication unit 1209 allows the device 1200 to exchange information/data through a computer network such as Internet and/or various types of telecommunication networks with other devices.

The computing unit 1201 may be various types of general and/or dedicated processing components with processing and computing abilities. Some examples of a computing unit 1201 include but not limited to a central processing unit (CPU), a graphics processing unit (GPU), various dedicated artificial intelligence (AI) computing chips, various computing units on which a machine learning model algorithm is running, a digital signal processor (DSP), and any appropriate processor, controller, microcontroller, etc. The computing unit 1201 executes various methods and processes as described above, for example, a method for processing a model operator. For example, in some embodiments, the method for processing a model operator may be further implemented as a computer software program, which is tangibly contained in a machine readable medium, such as the storage unit 1208. In some embodiments, a part or all of the computer program may be loaded and/or installed on the device 1200 via the ROM 1202 and/or the communication unit 1209.

When the computer program is loaded on the RAM 1203 and executed by the computing unit 1201, one or more steps in the method for processing a model operator may be performed as described above. Optionally, in other embodiments, the computing unit 1201 may be configured to the method for processing a model operator in other appropriate ways (for example, by virtue of a firmware).

Various implementations of the systems and techniques described above may be implemented by a digital electronic circuit system, an integrated circuit system, Field Programmable Gate Arrays (FPGAs), Application Specific Integrated Circuits (ASICs), Application Specific Standard Products (ASSPs), System on Chip (SOCs), Load programmable logic devices (CPLDs), computer hardware, firmware, software, and/or a combination thereof. These various embodiments may be implemented in one or more computer programs, the one or more computer programs may be executed and/or interpreted on a programmable system including at least one programmable processor, which may be a dedicated or general programmable processor for receiving data and instructions from the storage system, at least one input device and at least one output device, and transmitting the data and instructions to the storage system, the at least one input device and the at least one output device.

The program code configured to implement the method of the disclosure may be written in any combination of one or more programming languages. These program codes may be provided to the processors or controllers of general-purpose computers, dedicated computers, or other programmable data processing devices, so that the program codes, when executed by the processors or controllers, enable the functions/operations specified in the flowchart and/or block diagram to be implemented. The program code may be executed entirely on the machine, partly executed on the machine, partly executed on the machine and partly executed on the remote machine as an independent software package, or entirely executed on the remote machine or server.

In the context of the disclosure, a machine-readable medium may be a tangible medium that may contain or store a program for use by or in combination with an instruction execution system, apparatus, or device. The machine-readable medium may be a machine-readable signal medium or a machine-readable storage medium. A machine-readable medium may include, but is not limited to, an electronic, magnetic, optical, electromagnetic, infrared, or semiconductor system, apparatus, or device, or any suitable combination of the foregoing. More specific examples of machine-readable storage media include electrical connections based on one or more wires, portable computer disks, hard disks, RAMs, ROMs, Electrically Programmable Read-Only-Memory (EPROM), fiber optics, Compact Disc Read-Only Memories (CD-ROM), optical storage devices, magnetic storage devices, or any suitable combination of the foregoing.

In order to provide interaction with a user, the systems and techniques described herein may be implemented on a computer having a display device (e.g., a Cathode Ray Tube (CRT) or a Liquid Crystal Display (LCD) monitor for displaying information to a user); and a keyboard and pointing device (such as a mouse or trackball) through which the user can provide input to the computer. Other kinds of devices may also be used to provide interaction with the user. For example, the feedback provided to the user may be any form of sensory feedback (e.g., visual feedback, auditory feedback, or haptic feedback), and the input from the user may be received in any form (including acoustic input, voice input, or tactile input).

The systems and technologies described herein can be implemented in a computing system that includes background components (for example, a data server), or a computing system that includes middleware components (for example, an application server), or a computing system that includes front-end components (for example, a user computer with a graphical user interface or a web browser, through which the user can interact with the implementation of the systems and technologies described herein), or include such background components, intermediate computing components, or any combination of front-end components. The components of the system may be interconnected by any form or medium of digital data communication (e.g., a communication network). Examples of communication networks include: a Local Area Network (LAN), a Wide Area Network (WAN), the Internet and a block-chain network.

The computer system may include a client and a server. The client and server are generally remote from each other and interacting through a communication network. The client-server relation is generated by computer programs running on the respective computers and having a client-server relation with each other. The server may be a cloud server, a server of a distributed system, or a server combined with a block-chain.

It should be understood that the various forms of processes shown above can be used to reorder, add or delete steps. For example, the steps described in the disclosure could be performed in parallel, sequentially, or in a different order, as long as the desired result of the technical solution disclosed in the disclosure is achieved, which is not limited herein.

The above specific embodiments do not constitute a limitation on the protection scope of the disclosure. Those skilled in the art should understand that various modifications, combinations, sub-combinations and substitutions can be made according to design requirements and other factors. Any modification, equivalent replacement and improvement made within the spirit and principle of the disclosure shall be included in the protection scope of the disclosure.

What is claimed is:

1. A method for processing a model operator, comprising:
determining an operator set for model networking, wherein the operator set comprises a plurality of operators;
determining a storage amount occupied by an output tensor of each operator in the operator set and a computation time period consumed in a forward computation of each operator in the operator set; and
determining a first operator participating in recomputation in a model from the operator set, based on the storage amounts and the computation time periods of the plurality of operators.

2. The method according to claim 1, wherein determining the first operator participating in the recomputation in the model from the operator set based on the storage amounts and the computation time periods of the plurality of operators comprises:
determining a recomputation evaluation parameter of each operator in the operator set based on the storage amount and the computation time period of the operator; and
determining the first operator participating in the recomputation in the model from the operator set, based on the recomputation evaluation parameters of the plurality of operators.

3. The method according to claim 2, wherein determining the recomputation evaluation parameter of each operator in the operator set based on the storage amount and the computation time period of the operator comprises:
obtaining a ratio of the storage amount to the computation time period, and determining the ratio as the recomputation evaluation parameter.

4. The method according to claim 2, wherein the greater the recomputation evaluation parameter of the operator, the greater a possibility that the operator participates in recomputation.

5. The method according to claim 2, wherein determining the first operator participating in the recomputation in the model from the operator set based on the recomputation evaluation parameters of the plurality of operators comprises:
sorting the plurality of operators in the operator set according to recomputation evaluation parameters of the plurality of operators, and selecting the first operator from the operator set based on a sorting result.

6. The method according to claim 2, wherein determining the first operator participating in the recomputation in the model from the operator set based on the recomputation evaluation parameters of the plurality of operators comprises:
comparing recomputation evaluation parameters of the plurality of operators in the operator set with a defined threshold respectively; and
selecting an operator with a recalculation evaluation parameter greater than or equal to the defined threshold as the first operator.

7. The method according to claim 1, wherein determining the operator set for the model networking comprises:
determining one or more candidate operators required during the model networking; and
determining operators of a target category from the one or more candidate operators, and obtaining the operator set by performing a merging process on the operators of the target category.

8. The method according to claim 7, wherein determining the operators of the target category from the one or more candidate operators and obtaining the operator set by performing the merging process on the operators of the target category comprises:
determining, for any candidate operator that belongs to the target category, a previous candidate operator adjacent to the any candidate operator, and obtaining a merged operator by merging the any candidate operator and the previous candidate operator; and
obtaining the operator set based on the merged operator and remaining candidate operators.

9. The method according to claim 7, wherein determining the operators of the target category from the one or more candidate operators comprises:
determining a candidate operator that does not require a forward input and a forward output during a backward computation as an operator of the target category.

10. The method according to claim 8, further comprising:
determining a recomputation evaluation parameter of the merged operator based on a storage amount and a computation time period of an output tensor of each candidate operator comprised in the merged operator.

11. The method according to claim 1, after determining the first operator participating in the recomputation in the model from the operator set, the method further comprising:
performing a forward computation of the model based on a forward logical order of the plurality of operators in the operator set, and releasing an intermediate result of the first operator; and
storing an intermediate result of a forward computation of a second operator other than the first operator in the operator set in a graphics memory, and skipping, based on the intermediate result of the second operator, a subsequent recomputation performed for the second operator.

12. The method according to claim 11, wherein skipping the subsequent recomputation performed for the second operator based on the intermediate result of the second operator comprises:
performing a forward computation based on a first logical order of the forward computations of the plurality of operators in the operator set;
obtaining an intermediate result of the forward computation of the first operator by performing a forward recomputation on the first operator based on a forward input of the first operator;
reading the intermediate result of the second operator from the graphics memory in a case where the forward computation reaches the second operator; and
performing a backward computation of the model based on the intermediate result of the first operator and the intermediate result of the second operator.

13. The method according to claim 12, wherein performing the backward computation of the model based on the intermediate result of the first operator and the intermediate result of the second operator comprises:
performing the backward computation according to a second logical order of backward computations of the plurality of operators in the operator set;
performing, for the first operator, the backward computation on the first operator based on the intermediate result of the first operator and a backward output of a previous operator of the first operator in the backward computation, obtaining a backward output of the first operator, and inputting the backward output of the first operator into a next operator of the first operator; and
reading the intermediate result of the second operator from the graphics memory in a case where the backward computation reaches the second operator, determining a backward output of the second operator based on the intermediate result of the second operator and a backward output of a previous operator of the second operator in the backward computation, and inputting the backward output of the second operator into a next operator of the second operator.

14. The method according to claim 12, further comprising:
storing, in the graphics memory, a forward input of an operator on which the forward computation is first performed in a case where the forward computation of the model is performed for a first time; and
reading the forward input of the operator on which the forward computation is first performed from the graphics memory in a case where another forward computation is performed on the model, and performing a recomputation by inputting the forward input into the operator on which the forward computation is first performed.

15. The method according to claim 5, wherein sorting the plurality of operators in the operator set according to the recomputation evaluation parameters of the plurality of operators and selecting the first operator from the operator set based on the sorting result comprises:
sorting the plurality of operators in the operator set in a descending order of the recomputation evaluation parameters of the plurality of operators, and selecting top N operators as the first operator; or,
sorting the plurality of operators in the operator set in an ascending order of the recomputation evaluation parameters of the plurality of operators, and selecting bottom N operators as the first operator; and
wherein N is a natural number greater than or equal to 1.

16. An electronic device, comprising:
at least one processor; and
a memory communicatively coupled to the at least one processor;
wherein the memory stores instructions executable by the at least one processor, the processor is configured to:
determine an operator set for model networking, wherein the operator set comprises a plurality of operators;
determine a storage amount occupied by an output tensor of each operator in the operator set and a computation time period consumed in a forward computation of each operator in the operator set; and
determine a first operator participating in recomputation in a model from the operator set, based on the storage amounts and the computation time periods of the plurality of operators.

17. The electronic device according to claim 16, wherein, when determining the first operator participating in the recomputation in the model from the operator set based on the storage amounts and the computation time periods of the plurality of operators, the processor is configured to:
determine a recomputation evaluation parameter of each operator in the operator set based on the storage amount and the computation time period of the operator; and
determine the first operator participating in the recomputation in the model from the operator set, based on the recomputation evaluation parameters of the plurality of operators.

18. The electronic device according to claim 17, wherein, when determining the recomputation evaluation parameter of each operator in the operator set based on the storage amount and the computation time period of the operator, the processor is configured to:
obtain a ratio of the storage amount to the computation time period, and determine the ratio as the recomputation evaluation parameter.

19. The electronic device according to claim 17, wherein the greater the recomputation evaluation parameter of the operator, the greater a possibility that the operator participates in recomputation.

20. A non-transitory computer-readable storage medium with computer instructions stored thereon, wherein the computer instructions are configured to cause the computer to perform:
determining an operator set for model networking, wherein the operator set comprises a plurality of operators;
determining a storage amount occupied by an output tensor of each operator in the operator set and a computation time period consumed in a forward computation of each operator in the operator set; and
determining a first operator participating in recomputation in a model from the operator set, based on the storage amounts and the computation time periods of the plurality of operators.
